(19) United States
(12) Patent Application Publication
(10) Pub. No.: US 2026/0189205 A1
(43) Pub. Date: Jul. 2, 2026

(54) POWER AMPLIFIER DEVICE

(71) Applicant: Murata Manufacturing Co., Ltd., Nagaokakyo-shi (JP)

(72) Inventors: Yosuke SUSA, Nagaokakyo-shi (JP); Takaaki BENI, Nagaokakyo-shi (JP)

(21) Appl. No.: 19/416,284

(22) Filed: Dec. 11, 2025

(30) Foreign Application Priority Data
Dec. 27, 2024 (JP) 2024-231689

(51) Int. Cl. H03F 3/72; H03F 3/24

(52) U.S. Cl. CPC H03F 3/72; H03F 3/245; H03F 2200/444; H03F 2200/451; H03F 2203/7206

(57) ABSTRACT

A power amplifier device includes a bias switching circuit and a power amplifier circuit. The bias switching circuit performs switching between a first connection state and a second connection state based on a control signal. In the first connection state, a first power supply end and a power supply end are electrically connected, the first power supply end being electrically connected to a regulated power supply that supplies a first voltage that is constant. In the second connection state, a second power supply end and the supply end are electrically connected, the second power supply end being electrically connected to a variable power supply that supplies a second voltage that varies. The power amplifier circuit includes a first amplifying transistor and a second amplifying transistor.

### CROSS REFERENCE TO RELATED APPLICATION

This application claims priority from Japanese Patent Application No. 2024-231689, filed on Dec. 27, 2024. The content of these applications are incorporated herein by reference in its entirety.

### BACKGROUND OF THE DISCLOSURE

### 1. Field of the Disclosure

The present disclosure relates to a power amplifier device.

### 2. Description of the Related Art

There is known a power amplifier circuit including a plurality of cascode-connected transistors and an impedance switching unit for controlling respective bias voltages of the plurality of transistors (for example, see the specification of U.S. Patent Application Publication No. 2018/0131327).

### BRIEF SUMMARY OF THE DISCLOSURE

The power amplifier circuit described in the specification of U.S. Patent Application Publication No. 2018/0131327 includes a power amplifier that receives bias from a variable power supply. The power amplifier includes the plurality of cascode-connected transistors. A predetermined transistor of the plurality of transistors is provided with an impedance conversion unit. The impedance conversion unit performs switching of impedance viewed from the gate of the predetermined transistor between a standby mode in which a power amplifier does not output a signal and an active mode in which the power amplifier outputs a signal. The power amplifier circuit may thereby supply a desired bias voltage to the gate of the predetermined transistor and avoid deterioration of the output characteristics of the predetermined transistor.

However, to obtain a desired bias voltage in each of the plurality of cascode-connected transistors, the impedance conversion unit is required for each transistor. For this reason, the power amplifier circuit has a large circuit size, which causes an issue of complicated control of the impedance conversion unit.

Hence, it is a possible benefit of the present disclosure to improve the output characteristics of the power amplifier circuit including cascode-connected transistors by using a simplified circuit configuration.

A power amplifier device according to an aspect of the present disclosure includes a bias switching circuit and a power amplifier circuit. The bias switching circuit performs switching between a first connection state and a second connection state based on a control signal. In the first connection state, a first power supply end and a power supply end are electrically connected, the first power supply end being electrically connected to a regulated power supply that supplies a first voltage that is constant. In the second connection state, a second power supply end and the supply end are electrically connected, the second power supply end being electrically connected to a variable power supply that supplies a second voltage that varies. The power amplifier circuit includes a first amplifying transistor and a second amplifying transistor. The first amplifying transistor is a field effect transistor including a bias end, an output end, and a connection end. The bias end is electrically connected to the supply end with a first resistor element interposed therebetween, and the output end is electrically connected to a power supply. The second amplifying transistor is a field effect transistor including an input end, an amplification end, and a ground end. The amplification end is connected in series to a connection end of the first amplifying transistor, and the ground end is electrically connected to ground. The power amplifier circuit outputs an amplified signal from the output end of the first amplifying transistor, the amplified signal being obtained by amplifying an input signal to be inputted to the input end of the second amplifying transistor.

According to the present disclosure, the output characteristics of the power amplifier circuit including the cascode-connected transistors may be improved by using a simplified circuit configuration.

### BRIEF DESCRIPTION OF THE SEVERAL VIEWS OF THE DRAWINGS

FIG. 1 is a diagram illustrating an example configuration of various circuits for a power amplifier device that is an embodiment of the present disclosure;

FIG. 2 is a table illustrating an example of the operation states of elements in operation modes of the power amplifier device;

FIG. 3 is a diagram illustrating an example of the respective operation states of the elements in a low power mode; and

FIG. 4 is a diagram illustrating the respective operation states of the elements in a high power mode.

### DETAILED DESCRIPTION OF THE DISCLOSURE

Hereinafter, an embodiment of the present disclosure will be described with reference to the drawings. Circuit elements denoted by the same reference numeral represent the same circuit element, and repeated explanation is omitted.

### Configuration of Power Amplifier Device 10

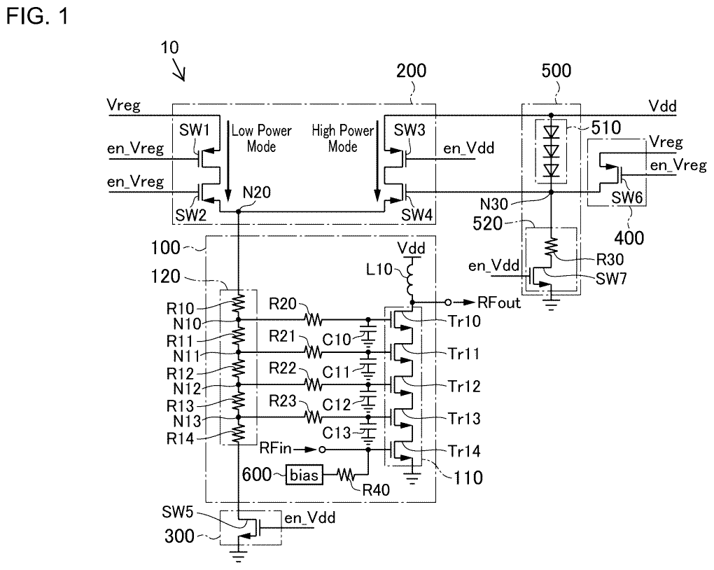

An overview of the configuration of a power amplifier device 10 will be described with reference to FIG. 1. FIG. 1 is a diagram illustrating an example configuration of various circuits for the power amplifier device 10 that is an embodiment of the present disclosure.

The power amplifier device 10 is included in a mobile communication apparatus such as a mobile phone and is used to amplify power of a radio-frequency (RF) signal to be transmitted to a base station. The power amplifier device 10 amplifies the power of signals specified in communication standards such as 2G (the second-generation mobile communication system), 3G (the third-generation mobile communication system), 4G (the fourth-generation mobile communication system), 5G (the fifth-generation mobile communication system), long term evolution (LTE)-frequency division duplex (FDD), LTE-time division duplex (LTE-TDD), LTE-Advanced, LTE-Advanced Pro, and 6G (sixth-generation mobile communication system). The frequency of a RF signal is in a range, for example, from approximately several hundred MHz to several ten GHz. The communication standards for signals amplified by the power amplifier device 10 is not limited to these standards.

As illustrated in FIG. 1, the power amplifier device 10 includes, for example, a power amplifier circuit 100, a bias switching circuit 200, a current switching circuit 300, a control circuit 400, and a withstand-voltage circuit 500.

The power amplifier circuit 100 is a circuit that amplifies an input signal RFin and outputs an amplified signal RFout. The power amplifier circuit 100 is electrically connected to a variable power supply Vdd that supplies a variable voltage. The power amplifier circuit 100 receives bias appropriate for one of a plurality of different output modes via the bias switching circuits 200. Specifically, the power amplifier circuit 100 is electrically connected to one of a regulated power supply Vreg that supplies a constant voltage and the variable power supply Vdd that supplies a variable voltage, with the bias switching circuit 200 interposed therebetween. The variable power supply Vdd may be a power supply based on an envelope tracking (ET) method and may also be a power supply based on an average power tracking (APT) method.

Hereinafter, in the power amplifier circuit 100, a state at the time of predetermined output is referred to as a low power mode, and a state at the time of output higher than that in the low power mode is referred to as a high power mode. The power amplifier circuit 100 receives bias appropriate for one of the low power mode and the high power mode via the bias switching circuit 200.

The bias switching circuit 200 is a circuit that supplies bias to the power amplifier circuit 100 in such a manner as to perform switching in a state of connection between the power amplifier circuit 100 and one of the regulated power supply Vreg for the constant voltage and the variable power supply Vdd, the switching being performed based on a control signal and appropriately for one of the low power mode and the high power mode. The bias switching circuit 200 includes a first power supply end electrically connected to the regulated power supply Vreg, a second power supply end electrically connected to the variable power supply Vdd, and a supply end for supplying the constant voltage of the regulated power supply Vreg and the variable voltage of the variable power supply Vdd to the power amplifier circuit 100.

Hereinafter, a state where the first power supply end and the supply end are electrically connected is referred to as a first connection state. The first connection state is thus a connection state in the low power mode and denotes a connection state where the constant voltage of the regulated power supply Vreg is suppliable as bias to the power amplifier circuit 100. A state where the second power supply end and the supply end are electrically connected is referred to as a second connection state. The second connection state is thus a connection state in the high power mode and denotes a connection state where the variable voltage of the variable power supply Vdd is suppliable as bias to the power amplifier circuit 100.

The current switching circuit 300 is a circuit for enabling an appropriate bias voltage to be supplied to the power amplifier circuit 100 in the low power mode. The current switching circuit 300 turns on or off appropriately for one of the low power mode and the high power mode. For example, the current switching circuit 300 turns off in the low power mode and turns on in the high power mode.

The control circuit 400 is a circuit for the bias switching circuit 200 to prevent current from reversing from the regulated power supply Vreg to the variable power supply Vdd in the low power mode (first connection state). The control circuit 400 electrically isolates a path between the regulated power supply Vreg and the variable power supply Vdd in the low power mode.

The withstand-voltage circuit 500 is a circuit for the bias switching circuit 200 to ensure the withstand voltage of the bias switching circuit 200 with respect to the variable voltage of the variable power supply Vdd in the high power mode (second connection state).

### Power Amplifier Circuit 100

As illustrated in FIG. 1, the power amplifier circuit 100 includes a cascode circuit 110 and a voltage divider circuit 120.

The cascode circuit 110 is a circuit in which a plurality of transistors are cascode-connected. FIG. 1 illustrates, as an example, the plurality of transistors that are composed of five-stage transistors Tr10 to Tr14 and that serve as field effect transistors. Hereinafter, the transistor Tr10 and the transistor Tr14 are respectively referred to as a first amplifying transistor and a second amplifying transistor on occasions.

The voltage divider circuit 120 is a circuit in which a plurality of resistor elements are connected in series. Each of nodes connecting a corresponding one of the plurality of resistor elements is electrically connected to a gate of a corresponding one of the transistors Tr10 to Tr13. Hereinafter, the plurality of resistor elements are referred to as resistor elements R10 to R14, and the nodes are referred to as nodes N10 to N13.

Specifically, the transistor Tr10 (first amplifying transistor) is a field effect transistor including a bias end, an output end, and a connection end. The bias end is, for example, a gate electrically connected to the node N10 with the resistor element R20 interposed therebetween. The bias end is thus electrically connected to the supply end of the bias switching circuit 200 with the node N10 and the resistor element R10 interposed therebetween. The output end is, for example, a drain electrically connected to the variable power supply Vdd with an inductor L10 interposed therebetween. The connection end is, for example, a source electrically connected to an amplification end of the transistor Tr11.

Hereinafter, description is provided, with the bias end, the output end, and the connection end in the transistor Tr10 being respectively referred to as a gate, a drain, and a source.

The transistors Tr11 to Tr13 are field effect transistors cascode-connected to the transistor Tr10. The gate of each of the transistors Tr11 to Tr13 is electrically connected to a corresponding one of the nodes N11 to N13 with a corresponding one of the resistor elements R21 to R23 interposed therebetween.

The transistor Tr14 (second amplifying transistor) is a field effect transistor cascode-connected to the transistors Tr10 to Tr13. The transistor Tr14 includes an input end, an amplification end, and a ground end. The input end is, for example, a gate that receives the input signal RFin. The input end receives a bias voltage Vg1 from a bias circuit 600 via a resistor element R40. The amplification end is, for example, a drain electrically connected to the source of the transistor Tr13. The ground end is, for example, a source electrically connected to ground.

Hereinafter, description is provided, with an input end, the amplification end, and the ground end in the transistor Tr14 being respectively referred to as a gate, a drain, and a source.

As described above, in the power amplifier circuit 100, the gate of each of the transistors Tr10 to Tr13 is electrically connected to the supply end of the bias switching circuit 200 with a corresponding one of the resistor elements R10 to R13 interposed therebetween. The constant voltage supplied from the regulated power supply Vreg or the variable voltage supplied from the variable power supply Vdd is divided as bias at the resistor elements R11 to R14 and supplied to the respective gates of the transistors Tr10 to Tr13. Hereinafter, the constant voltage supplied from the regulated power supply Vreg is referred to as a first voltage, and the variable voltage supplied from the variable power supply Vdd is referred to as a second voltage on occasions.

The power amplifier circuit 100 includes the transistors Tr10 to Tr14 in the five stages in the description above, but the configuration is not limited to this configuration. The power amplifier circuit 100 may include at least two-stage transistors that are cascode-connected and may include two cascode-connected transistors that are, for example, the transistor Tr10 and the transistor Tr14.

The power amplifier circuit 100 may also include capacitors C10 to C13 for reducing influence of a harmonic wave on the gate voltage, the capacitors C10 to C13 each being provided in parallel between the gate of a corresponding one of the transistors Tr10 to Tr13 and a corresponding one of the nodes N10 to N13.

### Bias Switching Circuit 200

As illustrated in FIG. 1, the bias switching circuit 200 includes a first switching element SW1, a first reverse-current protection element SW2, a second switching element SW3, and a second reverse-current protection element SW4. The first switching element SW1, the first reverse-current protection element SW2, the second switching element SW3, and the second reverse-current protection element SW4 are, for example, field effect transistors.

FIG. 1 illustrates, as an example, the first power supply end serving as a source of the first switching element SW1, the second power supply end serving as a source of the second switching element SW3, the supply end serving as a node N20 electrically connected to a source of the first reverse-current protection element SW2 and a source of the second reverse-current protection element SW4. Hereinafter, description is provided, with the first power supply end, the second power supply end, and the supply end in the bias switching circuit 200 being respectively referred to as the source of the first switching element SW1, the source of the second switching element SW3, and the node N20 on occasions.

The first switching element SW1 is a field effect transistor that turns on based on, for example, a first control signal en_Vreg. The first control signal en_Vreg is a signal outputted from, for example, an external controller (not illustrated) (such as an interface supporting a mobile industry processor interface (MIPI)) and is a signal indicating the low power mode.

Specifically, the first switching element SW1 includes the first power supply end, the first reverse-current element end, and the first output control end. The first power supply end (herein the first power supply end of the bias switching circuit 200) is, for example, the source electrically connected to the regulated power supply Vreg. The first reverse-current element end is, for example, the drain electrically connected to the drain of the first reverse-current protection element SW2. The first output control end is, for example, the gate that receives the first control signal en_Vreg. That is, in the first switching element SW1, the drain and the source enter a conduction state if the first control signal en_Vreg indicating the low power mode is inputted to the gate, and the drain and the source enter a non-conduction state if the first control signal en_Vreg is not inputted to the gate.

Hereinafter, description is provided, with the first power supply end, the first reverse-current element end, and the first output control end in the first switching element SW1 being respectively referred to as the source, the drain, and the gate.

The first reverse-current protection element SW2 is a switch that electrically allows isolation between the first switching element SW1 and the node N20 (supply end). In other words, the first reverse-current protection element SW2 is a switch that prevents current that passes through the second switching element SW3 (described later) from reversing to the regulated power supply Vreg.

Specifically, the first reverse-current protection element SW2 includes a first switching end, a first voltage supply end, and a first reverse-current control end. The first switching end is, for example, a drain electrically connected to the drain of the first switching element SW1. The first voltage supply end is, for example, a source electrically connected to the resistor element R10 with the supply end interposed therebetween. The first reverse-current control end is, for example, a gate that receives the first control signal en_Vreg. That is, in the first reverse-current protection element SW2, the drain and the source enter the conduction state if the first control signal en_Vreg indicating the low power mode is inputted to the gate, and the drain and the source enter the non-conduction state if the first control signal en_Vreg is not inputted to the gate. The first reverse-current protection element SW2 is thus controlled to perform operations identical to the on and off operations of the first switching element SW1.

Hereinafter, description is provided, with the first switching end, the first voltage supply end, and the first reverse-current control end in the first reverse-current protection element SW2 being respectively referred to as the drain, the source, and the gate.

The second switching element SW3 is a field effect transistor that turns on based on, for example, a second control signal en_Vdd. The second control signal en_Vdd is a signal outputted from, for example, an external controller (not illustrated) and is a signal indicating the high power mode.

Specifically, the second switching element SW3 includes a second power supply end, a second reverse-current element end, and a second output control end. The second power supply end (herein the second power supply end of the bias switching circuit 200 described above) is, for example, a source electrically connected to the variable power supply Vdd. The second reverse-current element end is, for example, a drain electrically connected to the drain of the second reverse-current protection element SW4. The second output control end is, for example, a gate that receives the second control signal en_Vdd. That is, in the second switching element SW3, the drain and the source enter the conduction state if the second control signal en_Vdd indicating the high power mode is inputted to the gate, and the drain and the source enter the non-conduction state if the second control signal en_Vdd is not inputted to the gate.

Hereinafter, description is provided, with the second power supply end, the second reverse-current element end, and the second output control end in the second switching element SW3 being respectively referred to as the source, the drain, and the gate.

The second reverse-current protection element SW4 is a switch that electrically allows isolation between the second switching element SW3 and the node N20 (supply end). In other words, the second reverse-current protection element SW4 is a switch that prevents current that passes through the first switching element SW1 from reversing to the variable power supply Vdd. The second reverse-current protection element SW4 operates based on the voltage supplied from the control circuit 400 in response to a first control switch SW6 turning on.

Specifically, the second reverse-current protection element SW4 includes a second switching end, a second voltage supply end, and a second reverse-current control end. The second switching end is a drain electrically connected to the drain of the second switching element SW3. The second voltage supply end is a source electrically connected to the resistor element R10 with the supply end interposed therebetween. A voltage that offsets the constant voltage of the regulated power supply Vreg (first voltage) applied to the second voltage supply end (source) is applied from the control circuit 400 to the second reverse-current control end in the low power mode (first connection state). This causes the second reverse-current protection element SW4 to turn off in the low power mode. In other words, the second reverse-current protection element SW4 is controlled to perform operations identical to the on and off operation of the second switching element SW3. As described above, in the second reverse-current protection element SW4, the drain and the source enter the conduction state in the high power mode, and the drain and the source enter the non-conduction state in the low power mode.

Hereinafter, description is provided, with the second switching end, the second voltage supply end, and the second reverse-current control end in the second reverse-current protection element SW4 being respectively referred to as the drain, the source, and the gate.

To date, in a power amplifier device without the bias switching circuit 200, a low voltage has supplied as bias from the variable power supply Vdd to the power amplifier circuit 100 in the low power mode. In this case, supplying, to the power amplifier circuit 100, bias preventing appropriate operation of the power amplifier circuit 100 causes an issue of deterioration of the output characteristics of the power amplifier circuit 100.

The power amplifier device 10 includes the bias switching circuit 200, and thereby an appropriate bias voltage may be supplied to the power amplifier circuit 100 in the low power mode. The power amplifier device 10 may thereby have improved output characteristics in the low power mode.

The operation of the second reverse-current protection element SW4 is not limited to the operation based on a voltage inputted from the control circuit 400. The second reverse-current protection element SW4 may operate based on the second control signal en_Vdd outputted from the controller. In this case, the power amplifier device 10 does not have to include the control circuit 400.

### Current Switching Circuit 300

As illustrated in FIG. 1, the current switching circuit 300 includes a current selector switch SW5. The current selector switch SW5 is, for example, a field effect transistor and includes a first current end, a second current end, and a current control end. The first current end is, for example, a drain connected in series to the supply end of the bias switching circuit 200 (node N20) with the resistor elements R10 to R14 interposed therebetween. The second current end is, for example, a source electrically connected to ground. The current control end is, for example, a gate that receives, for example, the second control signal en_Vdd.

Hereinafter, description is provided, with the first current end, the second current end, and the current control end in the current selector switch SW5 being respectively referred to as the drain, the source, and the gate.

The current selector switch SW5 causes non-conduction between the drain (first current end) and the source (second current end) in the low power mode (first connection state) and causes conduction between the drain and the source in the high power mode (second connection state). That is, in the current selector switch SW5, the drain and the source enter the conduction state if the second control signal en_Vdd indicating, for example, the high power mode is inputted to the gate, and the drain and the source enter the non-conduction state if the second control signal en_Vdd is not inputted to the gate.

The power amplifier device 10 includes the current switching circuit 300 and may thereby cause non-conduction between the supply end of the bias switching circuit 200 and ground electrically connected to the source of the current selector switch SW5 in the low power mode. The power amplifier device 10 may thus apply, as bias, the constant voltage supplied from the regulated power supply Vreg to the gates of the transistors Tr10 to Tr14 of the power amplifier circuit 100 without a voltage drop in the low power mode, without current flow between the supply end and ground. The power amplifier device 10 may thereby apply appropriate bias from the regulated power supply Vreg with a low constant voltage and thus have improved power efficiency and also improved output characteristics.

### Control Circuit 400

As illustrated in FIG. 1, the control circuit 400 includes the first control switch SW6. The first control switch SW6 is, for example, a field effect transistor and includes a first voltage end, a voltage output end, and a voltage control end. The first voltage end is, for example, a source that receives the constant voltage of the regulated power supply Vreg. The voltage output end is, for example, a drain electrically connected to the gate of the second reverse-current protection element SW4 to allow the constant voltage of the regulated power supply Vreg to be applied to the gate of the second reverse-current protection element SW4 (second reverse-current control end). The voltage control end is, for example, a gate that receives, for example, the first control signal en_Vreg.

Hereinafter, description is provided, with the first voltage end, the voltage output end, and the voltage control end in the first control switch SW6 being respectively referred to as the source, the drain, and the gate.

The first control switch SW6 causes conduction between the source (first voltage end) and the drain (voltage output end) in the low power mode (first connection state) and causes non-conduction between the source and the drain in the high power mode (second connection state). That is, in the first control switch SW6, the source and the drain enter the conduction state if the first control signal en_Vreg indicating, for example, the low power mode is inputted, and the source and the drain enter the non-conduction state if the first control signal en_Vreg is not inputted.

The power amplifier device 10 includes the control circuit 400 and thereby may cause the second reverse-current protection element SW4 to function in the low power mode regardless of a control signal outputted from the controller. Furthermore, the power amplifier device 10 includes the control circuit 400 and thereby may cause the second reverse-current protection element SW4 to operate appropriately even in the case where the withstand-voltage circuit 500 (described later) is provided. The power amplifier device 10 may thereby prevent current from reversing to the variable power supply Vdd with simple control steps and thus may have stably improved output characteristics.

### Withstand-Voltage Circuit 500

The withstand-voltage circuit 500 is a circuit for ensuring the withstand voltages of the second switching element SW3 and the second reverse-current protection element SW4, for example, in the second connection state. The withstand-voltage circuit 500 includes, for example, a diode circuit 510 and a second control switch SW7.

The diode circuit 510 is a circuit having at least one diode connected in series. In the diode circuit 510, an anode is electrically connected to the source of the second switching element SW3 (second power supply end), and a cathode is electrically connected to the gate of the second reverse-current protection element SW4 (second reverse-current control end). The cathode is electrically connected to, for example, a node N30 between a drain of the second control switch SW7 and the gate of the second reverse-current protection element SW4.

The diode circuit 510 may be designed to cause a voltage drop Vdio due to the diode of the diode circuit 510 to be lower than the withstand voltage of the second control switch SW7. This is designed to reliably prevent application of a voltage higher than or equal to the withstand voltage of the second control switch SW7.

The second control switch SW7 is a switch that operates based on the second control signal en_Vdd indicating the high power mode and is, for example, a field effect transistor. The second control switch SW7 is provided in series between the cathode and ground to allow the cathode of the diode circuit 510 to be electrically connected to ground.

Specifically, the second control switch SW7 includes a diode end, a control ground end, and a diode control end. The diode end is, for example, a drain connected in series to the cathode of the diode circuit 510 with a resistor element R30 interposed therebetween. The control ground end is, for example, a source electrically connected to ground. The diode control end is, for example, a gate that receives, for example, the second control signal en_Vdd.

Hereinafter, description is provided, with the diode end, the control ground end, and the diode control end in the second control switch SW7 being respectively referred to as the drain, the source, and the gate.

The power amplifier circuit 100 includes the withstand-voltage circuit 500, and thereby the withstand voltages of the second switching element SW3 and the second reverse-current protection element SW4 may be ensured in the high power mode by performing control to cause current to flow to the diode circuit 510. The power amplifier circuit 100 may thereby supply the voltage of the variable power supply Vdd as bias for the power amplifier circuit 100 in a state where the withstand voltage of the bias switching circuit 200 is ensured.

### Modification

In the description above, the power amplifier device 10 receives the first control signal en_Vreg and the second control signal en_Vdd from the controller (not illustrated); however, the configuration is not limited to this configuration. For example, the power amplifier device 10 may include a comparator (not illustrated) capable of comparing the variable voltage of the variable power supply Vdd (second voltage) with a predetermined voltage level. For example, if the variable voltage of the variable power supply Vdd is lower than or equal to the predetermined voltage level, the comparator outputs the first control signal en_Vreg to the gate of the first switching element SW1, the gate of the first reverse-current protection element SW2, and the gate of the first control switch SW6. In addition, for example, if the variable voltage of the variable power supply Vdd exceeds the predetermined voltage level, the comparator outputs the second control signal en_Vdd to the second switching element SW3 and the current selector switch SW5. The power amplifier device 10 may thereby operate rapidly due to the circuit configuration, not by control of the controller.

### Operations of Power Amplifier Device 10

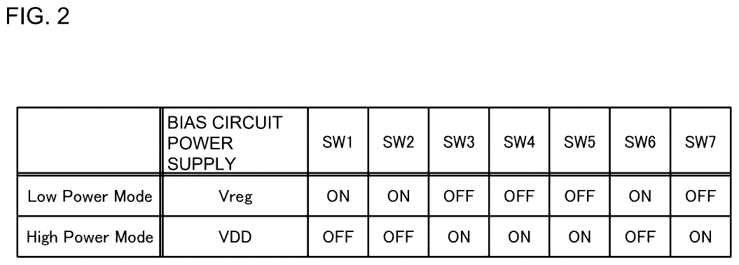

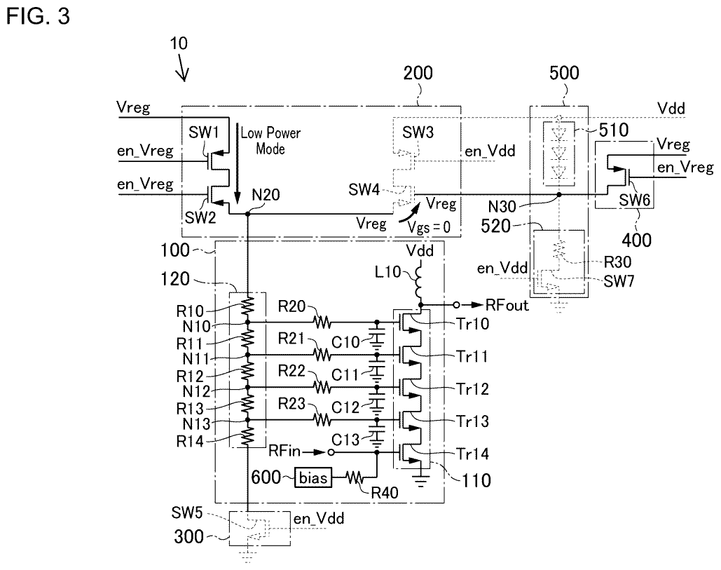

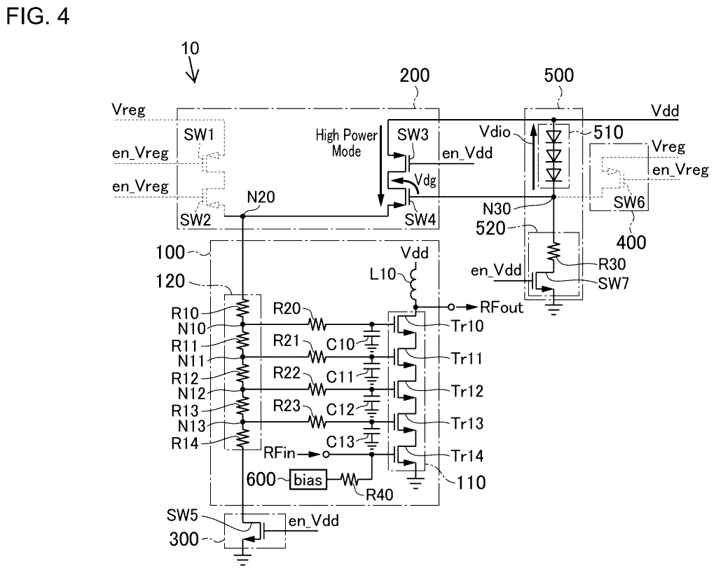

The operations of the power amplifier device 10 will be described with reference to FIGS. 2, 3, and 4. FIG. 2 is a table illustrating an example of the operation states of the elements in the operation modes of the power amplifier device 10. FIG. 3 is a diagram illustrating an example of the respective operation states of the elements in the low power mode. FIG. 4 is a diagram illustrating the respective operation states of the elements in the high power mode. FIGS. 3 and 4 conveniently illustrate switches in an on state and the system of the switches by using the solid lines and switches in an off state and the system of the switches by using the broken lines.

The power amplifier device 10 performs switching based on the control signal (the first control signal en_Vreg or the second control signal en_Vdd) outputted from the controller (not illustrated). If the variable voltage of the variable power supply Vdd is lower than or equal to the predetermined voltage level, the power amplifier device 10 performs switching to the first connection state that is the low power mode. If the variable voltage of the variable power supply Vdd exceeds the predetermined voltage level, the power amplifier device 10 performs switching to the second connection state that is the high power mode.

### Low Power Mode

First, the operations of the power amplifier device 10 in the first connection state as the low power mode will be described with reference to FIGS. 2 and 3.

As illustrated in FIG. 2, the first control signal en_Vreg is inputted to each of the gate of the first switching element SW1, the gate of the first reverse-current protection element SW2, and the gate of the first control switch SW6 in the first connection state. The drain and the source in each of the first switching element SW1, the first reverse-current protection element SW2, and the first control switch SW6 thereby enter the conduction state “ON”.

In this case, the second reverse-current protection element SW4 enters the non-conduction state “OFF” between the drain and the source. Specifically, as illustrated in FIG. 3, the constant voltage of the regulated power supply Vreg is applied to the source of the second reverse-current protection element SW4. In addition, the constant voltage of the regulated power supply Vreg is applied to the gate of the second reverse-current protection element SW4 via the first control switch SW6. The source voltage of the second reverse-current protection element SW4 and the gate voltage then become equal. Since a gate-to-source voltage Vgs becomes zero, the second reverse-current protection element SW4 turns off. The bias switching circuit 200 may thereby prevent current from reversing from the regulated power supply Vreg to the variable power supply Vdd in the first connection state.

In this case, the current selector switch SW5 is in the non-conduction state “OFF” between the drain and the source. In this case, current does not flow between the node N20 (power feeding end) in the bias switching circuit 200 and the drain of the current selector switch SW5. Since the resistor elements R10 to R14 do not have a voltage drop, the bias of the constant voltage of the regulated power supply Vreg is applied to the gates of the transistors Tr10 to Tr14 of the power amplifier circuit 100. The power amplifier circuit 100 may thereby amplify the input signal RFin and output the amplified signal RFout also in the low power mode, without the output characteristics deterioration.

In the low power mode in the power amplifier device 10, current may thus be prevented from reversing to the variable power supply Vdd, and the amplified signal RFout may also be outputted without the output characteristics deterioration.

### High Power Mode

The operations of the power amplifier device 10 in the second connection state as the high power mode will then be described with reference to FIGS. 2 and 4.

As illustrated in FIG. 2, in the second connection state, the second control signal en_Vdd is inputted to each of the gate of the second switching element SW3, the gate of the current selector switch SW5, and the gate of the second control switch SW7. The drain and the source in each of the second switching element SW3, the current selector switch SW5, and the second control switch SW7 thereby enter the conduction state “ON”.

The first control switch SW6 turns off, and the second control switch SW7 turns on. Current thus flows to the diode circuit 510. A voltage drop Vdio due to the diode occurs in the diode circuit 510. The diode circuit 510 is designed to have the voltage drop Vdio lower than the withstand voltage of the second reverse-current protection element SW4.

If the variable voltage of the variable power supply Vdd is lower than the withstand voltage of the second reverse-current protection element SW4, the gate voltage of the second reverse-current protection element SW4 is considered to be zero, and thus a drain-to-gate voltage Vdg of the second reverse-current protection element SW4 is considered to be equal to the variable voltage of the variable power supply Vdd. The drain-to-gate voltage Vdg lower than the withstand voltage is thus applied to the second reverse-current protection element SW4. Accordingly, if the variable voltage of the variable power supply Vdd is lower than the withstand voltage of the second reverse-current protection element SW4, the second reverse-current protection element SW4 is protected.

If the variable voltage of the variable power supply Vdd is higher than the withstand voltage of the second reverse-current protection element SW4, the gate voltage of the second reverse-current protection element SW4 is considered to be a voltage obtained by subtracting the voltage drop Vdio in the diode circuit 510 from the variable voltage of the variable power supply Vdd. The drain-to-gate voltage Vdg of the second reverse-current protection element SW4 is thus considered to be equal to the voltage drop Vdio in the diode circuit 510. Accordingly, the voltage drop Vdio in the diode circuit 510 is lower than the withstand voltage of the second reverse-current protection element SW4, and thus the second reverse-current protection element SW4 is protected.

As described above, in the power amplifier device 10, application of the high voltage to the second reverse-current protection element SW4 may be avoided due to the withstand-voltage circuit 500 in the high power mode, and the damage to the circuit may be avoided.

In the second connection state, the first reverse-current protection element SW2 turns off, and thus current is prevented from reversing from the variable power supply Vdd to the regulated power supply Vreg. In addition, the current selector switch SW5 is in the conduction state “ON” between the drain and the source in the second connection state. In this case, current flows between the node N20 (power feeding end) in the bias switching circuit 200 and the drain of the current selector switch SW5. The resistor elements R10 to R14 thus cause the variable voltage of the variable power supply Vdd to be divided to the gates of the transistors Tr10 to Tr14.

Therefore, with the power amplifier device 10, in the high power mode, current may be prevented from reversing to the regulated power supply Vreg, and the amplified signal RFout may be outputted without the output characteristics deterioration.

### Summarization

<1> A power amplifier device 10 includes a bias switching circuit 200 and a power amplifier circuit 100. The bias switching circuit 200 performs switching between a first connection state and a second connection state based on a control signal (for example, a first control signal en_Vreg or a second control signal en_Vdd). In the first connection state, a first power supply end (for example, a source of a first switching element SW1) and a supply end (for example, a node N20) are electrically connected, the first power supply end being electrically connected to a regulated power supply Vreg that supplies a constant voltage (first voltage) that is constant. In the second connection state, a second power supply end (for example, a source of a second switching element SW3) and the supply end (for example, the node N20) are electrically connected, the second power supply end being electrically connected to a variable power supply Vdd that supplies a variable voltage (second voltage) that varies. The power amplifier circuit 100 includes a first amplifying transistor and a second amplifying transistor. The first amplifying transistor (for example, a transistor Tr10) is a field effect transistor including a bias end (for example, a gate), an output end (for example, a drain), and a connection end (for example, a source). The bias end is electrically connected to the supply end with a first resistor element (for example, the resistor element R10) interposed therebetween, and the output end is electrically connected to a power supply. The second amplifying transistor (for example, a transistor Tr14) is a field effect transistor including an input end (for example, a gate), an amplification end (for example, a drain), and a ground end (for example, a source). The amplification end is connected in series to a connection end of the first amplifying transistor, and the ground end is electrically connected to ground. The power amplifier circuit 100 outputs an amplified signal RFout from the output end of the first amplifying transistor, the amplified signal RFout being obtained by amplifying an input signal RFin to be inputted to the input end of the second amplifying transistor. The power amplifier device 10 may thereby improve the output characteristics of a power amplifier circuit including cascode-connected transistors by using a simplified circuit configuration. Specifically, the power amplifier device 10 may thereby supply an appropriate bias voltage to the power amplifier circuit 100 in a low power mode and may thus improve the output characteristics.
<2> In the power amplifier device according to <1>, the power amplifier device 10 further includes a current selector switch SW5 including a first current end (for example, a drain of the current selector switch SW5), a second current end (for example, a source of the current selector switch SW5), and a current control end (for example, a gate of the current selector switch SW5). The first current end is connected in series to the supply end (for example, the node N20) with the first resistor element (for example, the resistor element R10) interposed therebetween. The second current end is electrically connected to ground. The current control end receives a control signal (for example, the second control signal en_Vdd). Based on the control signal (for example, the second control signal en_Vdd), the current selector switch SW5 causes non-conduction between the first current end and the second current end in the first connection state and causes conduction between the first current end and the second current end in the second connection state. The power amplifier device 10 may thereby supply bias from the regulated power supply Vreg with a low constant voltage and thus may improve power efficiency and output characteristics.
<3> In the power amplifier device according to <1> or <2>, in the power amplifier device 10, the bias switching circuit 200 includes the first switching element SW1, a first reverse-current protection element SW2, the second switching element SW3, and a second reverse-current protection element SW4. The first switching element SW1 turns on based on the first control signal en_Vreg that is the control signal for supplying the constant voltage (first voltage) from the supply end (for example, the node N20) and electrically performs connection between the first power supply end (for example, a source of the first switching element SW1) and the supply end. The first reverse-current protection element SW2 is provided in series between the first switching element SW1 and the supply end to electrically allow isolation between the first switching element SW1 and the supply end. The second switching element SW3 turns on based on the second control signal en_Vdd that is the control signal for supplying the variable voltage (second voltage) from the supply end and electrically performs connection between the second power supply end (for example, a source of the second switching element SW3) and the supply end. The second reverse-current protection element SW4 is provided in series between the second switching element SW3 and the supply end to electrically allow isolation between the second switching element SW3 and the supply end. The first reverse-current protection element SW2 is controlled to perform operations identical to operations of the first switching element SW1, and the second reverse-current protection element SW4 is controlled to perform operations identical to operations of the second switching element SW3. With the power amplifier device 10, the output characteristics of the power amplifier circuit including the cascode-connected transistors may thereby be improved by using a simplified circuit configuration.
<4> In the power amplifier device according to <3>, in the power amplifier device 10, the first reverse-current protection element SW2 includes a first switching end (for example, a drain), a first voltage supply end (for example, a source), and a first reverse-current control end (for example, a gate). The first switching end is electrically connected to the first switching element SW1, the first voltage supply end is electrically connected to the first resistor element (for example, the resistor element R10) with the supply end interposed therebetween, and the first reverse-current control end conductively connects the first switching end and the first voltage supply end, based on the first control signal en_Vreg. The second reverse-current protection element SW4 includes a second switching end (for example, a drain), a second voltage supply end (for example, a source), a second reverse-current control end (for example, a gate). The second switching end is electrically connected to the second switching element SW3, the second voltage supply end is electrically connected to the first resistor element (for example, the resistor element R10) with the supply end interposed therebetween, and the second reverse-current control end conductively connects the second switching end and the second voltage supply end, based on the constant voltage of an input voltage (for example, the regulated power supply Vreg supplied via a first control switch SW6). The power amplifier device 10 further includes the first control switch SW6. The first control switch SW6 is a field effect transistor including a first voltage end (for example, a source), a voltage output end (for example, a drain), and a voltage control end (for example, a gate). The first voltage end receives the constant voltage (first voltage), the voltage output end is electrically connected to the second reverse-current control end to allow application of the constant voltage (first voltage) to the second reverse-current control end, and the voltage control end conductively connects the first voltage end and the voltage output end, based on the first control signal en_Vreg. The power amplifier device 10 may thereby prevent current from reversing to the variable power supply Vdd with simple control steps and thus may stably improve the output characteristics.
<5> In the power amplifier device according to <3> or <4>, in the power amplifier device 10, the second switching element SW3 is a field effect transistor including a second power supply end (for example, the source of the second switching element SW3), a second reverse-current element end (reverse-current element end) (for example, a drain), and a second output control end (output control end) (for example, a gate). The second reverse-current element end (reverse-current element end) is electrically connected to the second switching end, and the second output control end (output control end) conductively connects the second power supply end and the second reverse-current element end (reverse-current element end), based on the second control signal en_Vdd. The power amplifier device 10 further includes a withstand-voltage circuit 500. The withstand-voltage circuit 500 includes a diode circuit 510 and a second control switch SW7. In the diode circuit 510, an anode is electrically connected to the second power supply end of the second switching element SW3, and a cathode is electrically connected to the second reverse-current control end of the second reverse-current protection element SW4. The second control switch SW7 is provided in series between the cathode and ground to turn on based on the second control signal en_Vdd and then to cause the cathode to be electrically connected to ground. The power amplifier device 10 may thereby supply the voltage of the variable power supply Vdd as bias for the power amplifier circuit 100 in a state where the withstand voltage of the bias switching circuit 200 is ensured.

The embodiment described above is provided for easier understanding of the present disclosure and is not intended to limit the interpretation of the present disclosure. The present disclosure may be changed or improved without departing from the spirit thereof and includes its equivalents. That is, an embodiment subjected to a design change appropriately by those skilled in the art is included in the scope of the present disclosure as long as the changed embodiment has the feature of the present disclosure. The elements, the arrangement thereof, and the like in the embodiment are not limited to those exemplified and may be changed appropriately.

What is claimed is:

1. A power amplifier device comprising:
a power amplifier circuit comprising:
a bias switching circuit,
a first amplifying transistor, and
a second amplifying transistor,
wherein the bias switching circuit is configured to switch between a first connection state and a second connection state, the switching being performed based on a control signal,
wherein in the first connection state, a first power supply end and a supply end are electrically connected, the first power supply end being electrically connected to a regulated power supply that supplies a first voltage that is constant,
wherein in the second connection state, a second power supply end and the supply end are electrically connected, the second power supply end being electrically connected to a variable power supply that supplies a second voltage that varies,
wherein the first amplifying transistor is a field effect transistor having a bias end, an output end, and a connection end,
wherein the bias end is electrically connected to the supply end with a first resistor circuit element interposed between the bias end and the supply end,
wherein the output end is electrically connected to a power supply,
wherein the second amplifying transistor is a field effect transistor having an input end, an amplification end, and a ground end,
wherein the amplification end is connected in series to the connection end of the first amplifying transistor,
wherein the ground end is electrically connected to ground, and
wherein the power amplifier circuit is configured to output an amplified signal from the output end of the first amplifying transistor, the amplified signal being obtained by amplifying an input signal input to the input end of the second amplifying transistor.

2. The power amplifier device according to claim 1, further comprising:
a current selector switch having a first current end, a second current end, and a current control end,
wherein the first current end is connected in series to the supply end with the first resistor element interposed between the first current end and the supply end,
wherein the second current end is electrically connected to the ground,
wherein the current control end receives a control signal, and
wherein based on the control signal, the current selector switch causes non-conduction between the first current end and the second current end in the first connection state and causes conduction between the first current end and the second current end in the second connection state.

3. The power amplifier device according to claim 1,
wherein the bias switching circuit comprises:
a first switching element configured to turn on based on a first control signal serving as the control signal for supplying the first voltage from the supply end, and that is configured to electrically connect the first power supply end to the supply end,
a first reverse-current protection element that is in series between the first switching element and the supply end, thereby electrically isolating the first switching element and the supply end,
a second switching element configured to turn on based on a second control signal serving as the control signal for supplying the second voltage from the supply end, and that is configured to electrically connect the second power supply end to the supply end, and
a second reverse-current protection element in series between the second switching element and the supply end, thereby electrically isolating the second switching element and the supply end,
wherein the first reverse-current protection element is controlled to perform operation identical to operation of the first switching element, and
wherein the second reverse-current protection element is controlled to perform operation identical to operation of the second switching element.

4. The power amplifier device according to claim 2,
wherein the bias switching circuit comprises:
a first switching element configured to turn on based on a first control signal serving as the control signal for supplying the first voltage from the supply end, and that is configured to electrically connect the first power supply end to the supply end,
a first reverse-current protection element that is in series between the first switching element and the supply end, thereby electrically isolating the first switching element and the supply end,
a second switching element configured to turn on based on a second control signal serving as the control signal for supplying the second voltage from the supply end, and that is configured to electrically connect the second power supply end to the supply end, and
a second reverse-current protection element in series between the second switching element and the supply end, thereby electrically isolating the second switching element and the supply end,
wherein the first reverse-current protection element is controlled to perform operation identical to operation of the first switching element, and
wherein the second reverse-current protection element is controlled to perform operation identical to operation of the second switching element.

5. The power amplifier device according to claim 3,
wherein the first reverse-current protection element has a first switching end, a first voltage supply end, and a first reverse-current control end,
wherein the first switching end is electrically connected to the first switching element,
wherein the first voltage supply end is electrically connected to the first resistor element with the supply end interposed between the first voltage supply end and the first resistor element,
wherein based on the first control signal, the first reverse-current control end causes the first switching end and the first voltage supply end to turn on,
wherein the second reverse-current protection element has a second switching end, a second voltage supply end, and a second reverse-current control end,
wherein the second switching end is electrically connected to the second switching element,
wherein the second voltage supply end is electrically connected to the first resistor element with the supply end interposed between the second voltage supply end and the first resistor element,
wherein the second reverse-current control end conductively connects the second switching end and the second voltage supply end, based on an input voltage,
wherein the power amplifier device further comprises a first control switch,
wherein the first control switch is a field effect transistor having a first voltage end, a voltage output end, and a voltage control end,
wherein the first voltage end receives the first voltage,
wherein the voltage output end is electrically connected to the second reverse-current control end, thereby allowing application of the first voltage to the second reverse-current control end, and
wherein the voltage control end conductively connects the first voltage end and the voltage output end, based on the first control signal.

6. The power amplifier device according to claim 5,
wherein the second switching element is a field effect transistor having a second power supply end, a reverse-current element end, and an output control end,
wherein the reverse-current element end is electrically connected to the second switching end,
wherein the output control end conductively connects the second power supply end and the reverse-current element end, based on the second control signal,
wherein the power amplifier device further comprises a withstand-voltage circuit,
wherein the withstand-voltage circuit comprises a diode circuit and a second control switch,
wherein in the diode circuit, an anode is electrically connected to the second power supply end of the second switching element, and a cathode is electrically connected to the second reverse-current control end of the second reverse-current protection element, and
wherein the second control switch is in series between the cathode and the ground to turn on based on the second control signal and to electrically connect the cathode to the ground.
